(19) United States
(12) Patent Application Publication
(10) Pub. No.: US 2023/0309255 A1
(43) Pub. Date: Sep. 28, 2023

(54) SERVER CABINET

(71) Applicant: Sympateco, Inc., Omaha, NE (US)

(72) Inventors: Nathan Mackinley Davis, Pueblo, CO (US); Curt Brannon, Omaha, NE (US)

(21) Appl. No.: 18/188,165

(22) Filed: Mar. 22, 2023

Related U.S. Application Data
(60) Provisional application No. 63/322,345, filed on Mar. 22, 2022.

(51) Int. Cl. H05K 7/14; H05K 5/02; G07C 9/00; G07C 9/29; G06K 7/10

(52) U.S. Cl. CPC H05K 7/1488; H05K 5/0221; G07C 9/00182; G07C 9/29; G06K 7/10366

(57) ABSTRACT

A server cabinet is disclosed. The server cabinet can comprise a cabinet frame that includes a housing structure, and the housing structure includes an overhead structure. The server cabinet can also include a cabinet insert translationally connected to the overhead structure such that the cabinet insert can transition between a retracted orientation and an extended orientation, wherein the cabinet insert includes a pull-out basket assembly configured to support a plurality of baskets.

### INTRODUCTION

The present disclosure relates to a server cabinet. A cabinet is a cupboard with drawers or shelves for storing articles.

### SUMMARY

According to one aspect of the disclosure, a server cabinet includes a cabinet frame that includes a housing structure, and the housing structure includes an overhead structure. The server cabinet can also include a cabinet insert translationally connected to the overhead structure such that the cabinet insert can transition between a retracted orientation and an extended orientation, wherein the cabinet insert includes a pull-out basket assembly configured to support a plurality of baskets.

In one aspect, the overhead structure includes a first base structure and a second base structure, and a portion of the overhead frame is disposed between the first base structure and the second base structure.

In another aspect, the first base structure, the second base structure, and the overhead frame comprise aluminum having a hollow profile.

In another aspect, the server cabinet includes a rail system.

In another aspect, the rail system comprises a plurality of rails attached to the overhead frame and configured to retain rollers attached to the cabinet insert.

In another aspect, the server cabinet includes a lock that is configured to allow credentialed personnel access to a drawer within the cabinet insert.

In another aspect, the lock is a radio frequency identification (RFID) lock.

In another aspect, the lock communicates with a wearable device including a RFID wristband for accessing the drawer within the cabinet insert.

In another aspect, the lock communicates with a smart card, a smart tag, a smart key fob, and a smart identification badge for accessing the drawer within the cabinet insert.

In another aspect, wherein the lock includes a key lock cylinder and/or a digital keypad.

According to one aspect of the disclosure, a server cabinet includes a cabinet frame having a housing structure. The housing structure includes an overhead structure. The server cabinet further includes a cabinet insert translationally connected to the overhead structure such that the cabinet insert can transition between a retracted orientation and an extended orientation. The cabinet insert includes a pull-out basket assembly configured to support a plurality of baskets. The server cabinet further includes a keyboard tray attached to the cabinet insert. The keyboard tray is movable between a stowed position and a deployed position.

In one aspect, the server cabinet further includes a mount assembly for attaching the keyboard tray to the cabinet insert. The mount assembly includes a shuttle bracket that is movable relative to the cabin insert along a first axis between the stowed position and the deployed position.

In another aspect, the mount assembly further includes an arm attached to the shuttle bracket. The arm is pivotably attached to an end of the arm about a second axis that is perpendicular to the first axis. The keyboard tray is movable between a lowered position and a raised position in response to the arm pivoting about the second axis.

In another aspect, the shuttle bracket is pivotably attached to the cabin insert for pivoting the mount assembly about a third axis that is perpendicular to the first and second axes. The keyboard tray is movable between a first and second side positions.

In another aspect, the cabinet insert defines an interior space, with a mass scale stored in the interior space and the mass scale measuring a mass of items stored within the interior space.

In another aspect, the cabinet insert defines an interior space with a chute being accessible via an opening for delivering items to the interior space.

In another aspect, the overhead structure includes a first base structure and a second base structure. A portion of the overhead frame is disposed between the first base structure and the second base structure. The first base structure, the second base structure, and the overhead frame comprise aluminum have a hollow profile.

In another aspect, the server cabinet further includes a rail system having a plurality of rails attached to the overhead frame and configured to retain rollers attached to the cabinet insert. The server cabinet further includes a lock that is configured to allow credentialed personnel access to a drawer within the cabinet insert. The lock includes a radio frequency identification (RFID) lock, a key lock cylinder, and/or a digital keypad. The lock is actuated by a smart card, a smart tag, a smart key fob, a smart identification badge, and/or a wearable device for permitting access to the drawer within the cabinet insert.

According to one aspect of the disclosure, a method is provided for operating a server cabinet having a cabinet frame and a cabinet insert. The cabinet frame has a housing structure that includes an overhead structure. The cabinet insert is translationally connected to the overhead structure, and the cabinet insert includes a pull-out basket assembly configured to support a plurality of baskets. The server cabinet further includes a keyboard tray attached to the cabinet insert. The method includes translating the cabinet insert between a retracted orientation and an extended orientation. The method further includes allowing, using a lock, credentialed personnel access to a drawer within the cabinet insert. The lock includes a radio frequency identification (RFID) lock, a key lock cylinder, and/or a digital keypad. The lock is actuated by at least one of a smart card, a smart tag, a smart key fob, a smart identification badge, and/or a wearable device for permitting access to the drawer within the cabinet insert.

In one aspect, the method further includes moving the keyboard tray along a first axis relative to the cabinet insert between a stowed position and a deployed position. The method further includes pivoting the keyboard tray about a second axis between a lowered position and a raised position, with the second axis being perpendicular to the first axis. The method further includes pivoting the keyboard tray about a third axis between a first side position and a second side position, with the third axis being perpendicular to the first and second axes.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

The drawings described herein are for illustration purposes only and are not intended to limit the scope of the present disclosure in any way.

FIG. 1 is an isometric view of a cabinet according to an example implementation;

FIG. 2 is a side view of the cabinet according to an example implementation;

FIG. 3 is an isometric view of the cabinet according to an example implementation;

FIG. 4 is an isometric view of the cabinet according to an example implementation, where a cabinet insert is in a retracted orientation;

FIG. 5 is an isometric view of the cabinet according to an example implementation, where a cabinet insert is in an extended orientation;

FIG. 6 is another isometric view of the cabinet according to an example implementation;

FIG. 7 is a partially exploded view of the cabinet according to an example implementation;

FIG. 8 is an isometric view of a cabinet according to another example implementation, where a cabinet insert that defines an interior space with a chute being accessible via an opening for delivering items to the interior space;

FIG. 9 is an isometric view of a cabinet according to still another example implementation, where a cabinet insert that includes a keyboard tray, with the keyboard tray carrying a keyboard and being accessible via a pull-down cover panel;

FIG. 10 is a side view of the keyboard tray of FIG. 9, illustrating a mount assembly including a shuttle bracket connected to the cabinet insert, an arm attached to the shuttle bracket, and the keyboard tray attached to the arm, with the keyboard tray and being movable between a stowed position and a deployed position;

FIG. 11 is a side view of the keyboard tray of FIG. 10, illustrating the keyboard tray pivotably attached to an end of the arm;

FIG. 12 is an isometric view of the keyboard tray of FIG. 10, illustrating the keyboard tray movable between a lowered position and a raised position;

FIG. 13 is a front perspective view of the keyboard tray of FIG. 10, illustrating the keyboard tray movable pivoting between first and second side positions; and

FIG. 14 is a flow chart of one example of a method for operating the cabinet of FIG. 1,

### DETAILED DESCRIPTION

Cabinets to be installed in institutional environments, such as in medical settings, are typically constructed of simple laminate and generally do not include built-in organizational components to facilitate proper and efficient storage of goods, such as medical supplies.

As discussed in greater detail herein, a cabinet, also referred to as a server cabinet or a nurse server, is described that includes a cabinet insert. The cabinet insert can transition between an extended orientation and retracted orientation via a rail system. The rail system can comprise an overhead structure of the cabinet. The various frame components can comprise aluminum, such as aluminum having a hollow profile.

The cabinet can also include covered slide out smart phone induction charging for hospital staff, covered slide out smart phone induction charging for hospital staff, and/or covered slide out smart phone induction charging for hospital staff. As discussed herein, the cabinet can incorporate ultraviolet (UV) lights that mitigate the spread of bacteria and/or other pathogens.

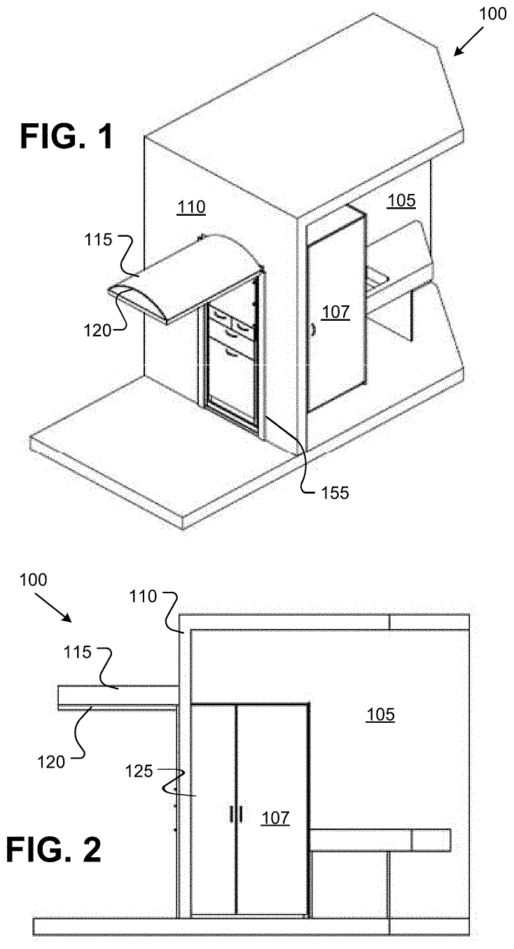

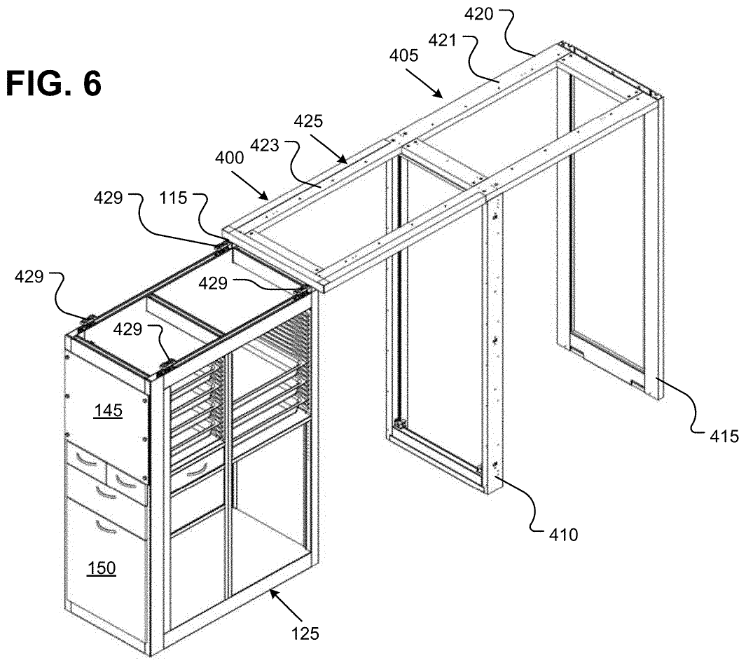

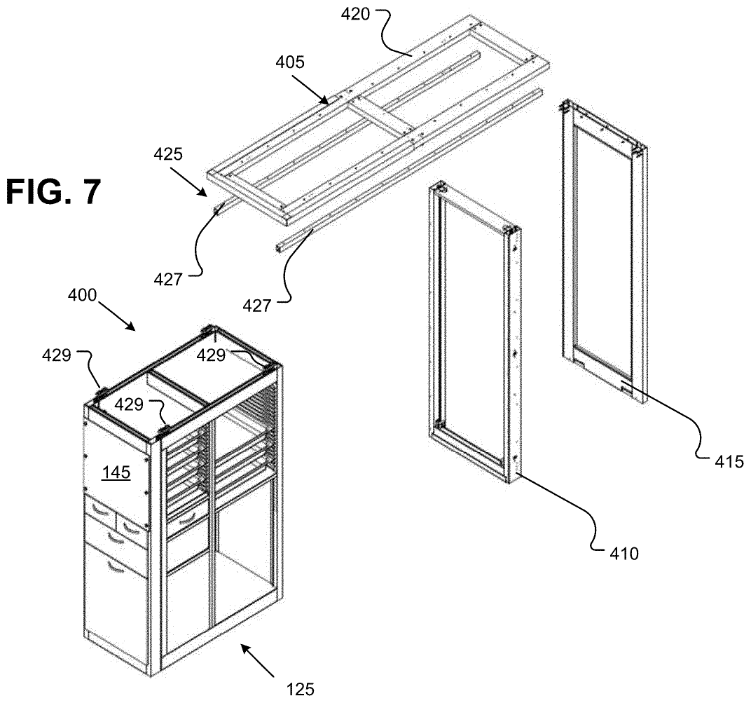

FIGS. 1 to 9 illustrate an example cabinet 100 in accordance with the present disclosure that can be used to facilitate exchange where supplies, linen, and other goods can be changed within a room 105 associated with a cabinet 100.

The cabinet 100 can be pre-fabricated and provided ready-to-install. The cabinet 100 can provide pass-through, non-pass-through, and pull-out units. As described below, basket systems with bidirectional bins that pull out and tilt down into both the corridor and the patient room can provide accessible, hands-free, vertical storage. The bins and basket system can be interchangeable on-site, and can be used with adjustable dividers, label holders, and the like. A bidirectional locking medication drawer can be included that pulls out into both the corridor, i.e., for stocking, and the patient room, i.e., for retrieval.

The cabinet 100 can be configured as modular pass-through server having flexibility to meet the needs of patients, staff, and facilities. As shown, the cabinet 100 can be placed into a cavity (not shown) defined within a wall 110 of the room 105. Installation and/or placement of the cabinet 100 can be performed by a vendor providing the cabinet 100 or by a general contractor.

An interior space can be provided for receiving and storing soiled linen, trash carts, heavy-duty metal hoppers, and other storage devices. In this manner, carts and/or hoppers can be hidden behind doors, and soiled materials can be disposed of from the hospital corridor. The cabinets 100 can also be used with locking systems, which can interface with current hospital security systems, e.g., in a plug-and-play manner, and may include one or more wireless keypads or other data entry devices.

As described herein, the cabinet 100 can be used for applications including, but not necessarily limited to: new hospital construction, new patient-room renovations and/or additions, emergency department renovations and/or additions, intensive care unit (ICU) department renovations and/or additions, labor and delivery renovations and/or additions, and so forth. The cabinet 100 described herein can facilitate dynamic workflow, organization, and ease of use for storing supplies, linens, and/or medications stocked at a patient-room level for nursing staff and supply departments. The cabinet 100 can improve the overall experience of patients, the efficiency of staff, the control of hospital acquired infections (HAIs), and so forth. In some embodiments, the cabinet 100 may be a pass-through cabinet.

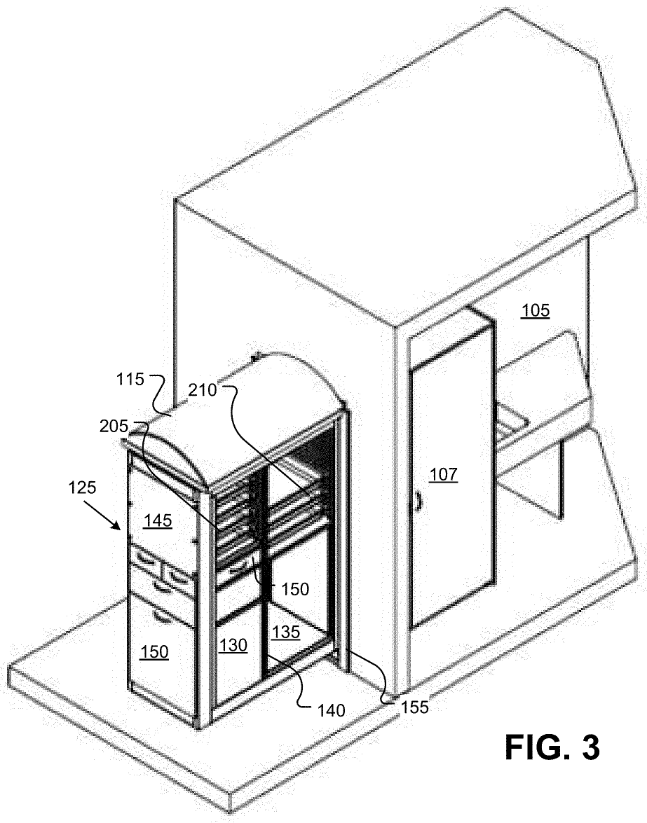

The cabinet 100 can include an overhead structure 115 that can include lighting structure 120, such as a parabolic lighting structure. The overhead structure 115 can be attached to the wall 110. When attached, the overhead structure 115 extends outwardly and can provide illumination when the cabinet 100 is in an extended orientation (see FIG. 3). When the cabinet 100 is in a retracted orientation, contents stored within the cabinet 100 can be accessed via a door 107 (see FIGS. 1 and 2).

As shown in FIG. 3, a cabinet 100 can include a cabinet insert 125 that defines at least a first interior space 130 and a second interior space 135 to form an enclosed region for storing supplies the first interior space 130 is separated from the second interior space 135 by at least one partition 140. The cabinet insert 125 can comprise the framework, i.e., frame portions constructed from aluminum as discussed herein.

In various implementations, portions of the cabinet 100 may be constructed using a wood material, a wood-based material, e.g., a laminate material, a composite material, and so on. For example, the cabinet one or more drawers 150 can include a thermofoil surface, a fire-rated laminate, and so forth. In some implementations, the drawers 150 can be formed from a high-pressure laminate or a thermo-fused laminate covering a particle board core. In some implementations, the cabinet insert 125 of the cabinet 100 may be constructed using a metal material, such as aluminum having a hollow profile, and so forth. However, aluminum is provided by way of example and is not meant to limit the present disclosure. In using aluminum having a hollow profile to form the structure of the cabinet, the cabinet 100 is structurally stronger, relatively lighter weight, and/or mitigates bacterial concerns.

As shown in FIG. 3, the cabinet 100 can include a gasket 155, e.g., a closed cell rubber gasket, on one or more openings to impede smoke, dust, and/or noise from entering a room 105. The gasket 155 may be used for smoke and/or draft control and acceptance. Profiles and clips may use a track for receiving a silicone-based gasket pressed into the track, which creates an impediment around the doors and/or drawers to smoke and/or dust infiltration when the cabinet is in a retracted orientation.

The cabinet 100 can further include a front mounted transparent cover 145 that can be used to protect a computer monitor when inserted into the cabinet insert 125. The cabinet 100 can also incorporate one or more ultraviolet (UV) lights within the cabinet insert 125. For example, UV lights may be installed through the cabinet insert 125, such as incorporated into shelving and various interior portions of the cabinet 100. This portion of the cabinet 100 can be configured to function as a desk. For example, portions of the cabinet 100 can retain keyboards, computing devices, monitors, and the like.

Referring generally to FIGS. 3 through 7, the interior spaces 130, 135 are configured to support a respective basket assembly 205 and/or provided to receive and store soiled linens, trash carts, hoppers, and other storage devices. For example, the first interior space 130 supports a pull-out basket assembly 205 including multiple baskets 210 stacked on top of one another. In some embodiments, the baskets 210 can be bi-directional pull-out baskets with adjustable modular dividers inside of each basket 210. This arrangement can facilitate a nurse server exchange system for supply management and restocking by, for instance, a central supply department, hospital logistics, and so forth.

In some implementations, the interior space 135 may include a mass scale 215, such as a digital scale, to measure mass of items stored within the interior space 135. For example, the mass scale 215 may be positioned within the interior space 135 such that the mass scale 215 can measure a mass associated with a receptacle stored in the interior space 135. The receptacle can be configured to store soiled linens, or the like. The mass scale 215 may also include a processor, memory, and/or a communication device. The processor can be programmed to determine whether the mass exceeds a predetermined mass threshold. If the mass exceeds the predetermined mass threshold, the processor can generate an alert that is transmitted via the communication device to alert personnel that the receptacle may require attention.

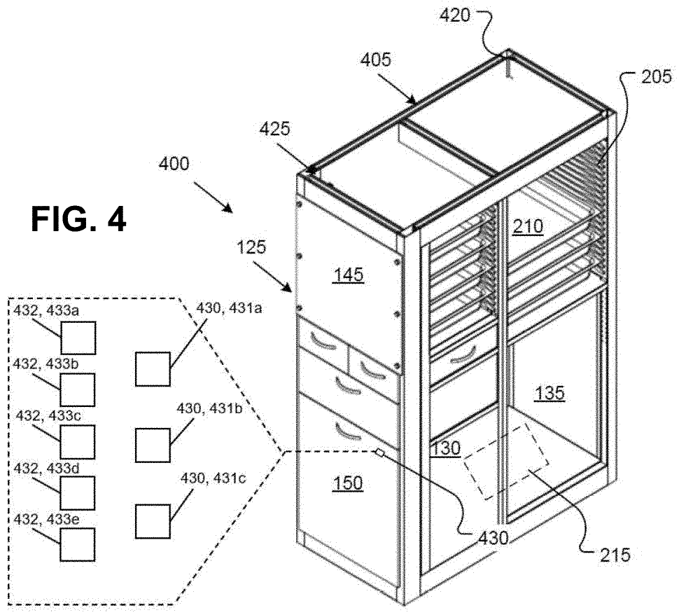

As shown in FIGS. 4 through 7, a cabinet frame 400 includes a housing structure 405 to retain the cabinet insert 125 when the cabinet insert is in the retracted orientation (see FIG. 4). The housing structure 405 includes a first base structure 410 and a second base structure 415. As discussed above, the base structures 410, 415 comprise aluminum having a hollow profile. The housing structure 405 also includes an overhead frame 420 disposed at least partially between the base structures 410, 415. The overhead frame 420 can include the overhead structure 115, and the overhead frame 420 can also comprise aluminum having a hollow profile. The overhead frame 420 can be configured as an “8”-frame in which the structural portions of the overhead frame 420 generally appear to form the number eight (8) when constructed. When constructed in the “8”-frame configuration, a first portion 421 of the overhead frame 420 is disposed between the base structures 410, 415, and a second portion 423 of the overhead frame 420 comprises the overhead structure 115.

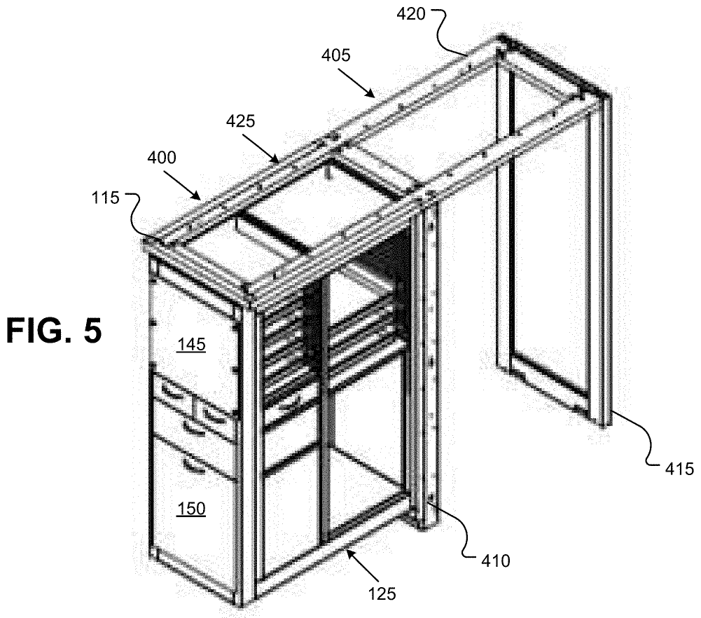

The overhead frame 420 also includes a rail system 425 to allow the cabinet insert 125 to transition between the extended orientation and the retracted orientation, i.e., translationally connected. In an example implementation, as shown in the cabinet insert 125 is supported using multiple rails 427 that are attached to the overhead frame 420. The cabinet insert 125 may include rollers 429 that are positioned within the rails 427 such that the cabinet insert 125 can transition between the retracted orientation (see FIG. 4) and the extended orientation (see FIG. 5).

Generally, the cabinet insert 125 may be extended from the housing structure 405 in a first direction, e.g., perpendicularly and into a hallway, and one or more components of the cabinet insert 125, i.e., a drawer 150, a basket 210, and so forth, may extend in a direction generally perpendicular to the extension of the cabinet insert 125. Further, one or more of the components of the cabinet insert 125, i.e., a drawer 150, a basket 210, and so forth may be extendable in one or more directions.

With reference to FIG. 4, in some implementations, a lock 430 may also be provided on an exterior panel of the drawer 150. The lock 430 can be provided using one or more locking technologies, including, but not necessarily limited to: a key lock cylinder 431a, a digital keypad 431b, a radio frequency identification (RFID) lock 431c, and so forth. In some embodiments, an RFID lock on a door and/or a medication drawer can be accessed using a wearable device 432. It should be noted that individual users and/or groups of users may be given different access to the various spaces within a cabinet 100. For example, one staff member, e.g., supply department personnel may have access to only a portion of the interior space while another staff member, e.g., a nurse, may have access to the first interior space 110 and the medication drawer. The lock 430 may be compatible with an existing hospital facility security system, and may allow access to hospital staff, e.g., a nurse, when used with hospital-issued identification, including, but not necessarily limited to: an RFID wristband 433a, a smart card 433b, a smart tag 433c, a smart key fob 433d, a smart identification badge 433e, and so forth.

The cabinet 100 can also include a proximity switch to control one or more operations of the cabinet 100. The proximity switch can detect movement, and based on the detected movement, perform an operation. For example, based on a detected movement, the cabinet 100 may extent and/or retract, power on or power down one or more lights within the cabinet 100, and so forth.

In some implementations, the cabinet 100 can further include electrical management devices and/or electrical panels. The electrical management device can allow cables and/or electrical wiring to be routed throughout the cabinet 100. Electrical wiring can be connected to the cabinet insert 125, i.e., pull-out cabinet insert, via a power-pantograph or electrical management device to power one or more proximity readers and/or locks, such as an access/control-type lock for a medication drawer that can interface with existing building and/or facility systems. Power can also be supplied to the cabinet insert 125 for electrically powering lighting, e.g., light emitting diode (LED) lighting.

The cabinet 100 can further include power outlets to allow various electronic devices to connect to alternating current (AC) mains. For example, the power outlets can comprise electrical plugs and/or sockets, such as Universal Serial Bus (USB) connectors, and the like.

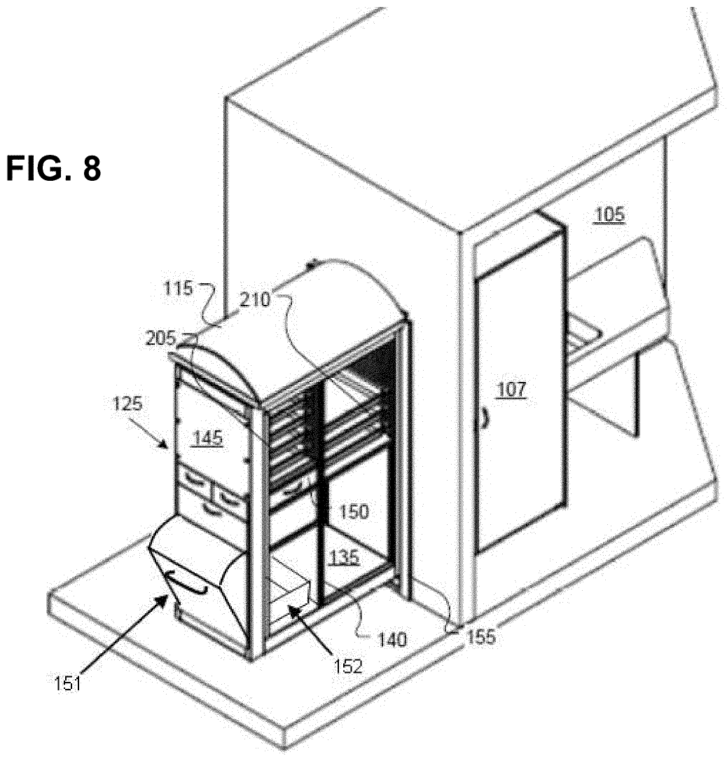

Referring to FIG. 8, another example of the cabinet 100 is similar to the cabinet 100 of FIGS. 1-7 and includes the same components identified by the same numbers. However, while the cabinet 100 of FIGS. 1-7, the cabinet 100 includes a pull-out drawer that can be disposed in the first interior space 130, the cabinet 100 of FIG. 8 includes a chute 151 that allows medical personnel to provide pharmaceuticals from the hospital corridor to the room 105. In other words, medical personnel can provide individuals with pharmaceuticals to a patient without entering the room 105. The chute can be accessible via an opening proximate to the hospital corridor such that the pharmaceuticals are deposited into a bin 152 within the interior space 130.

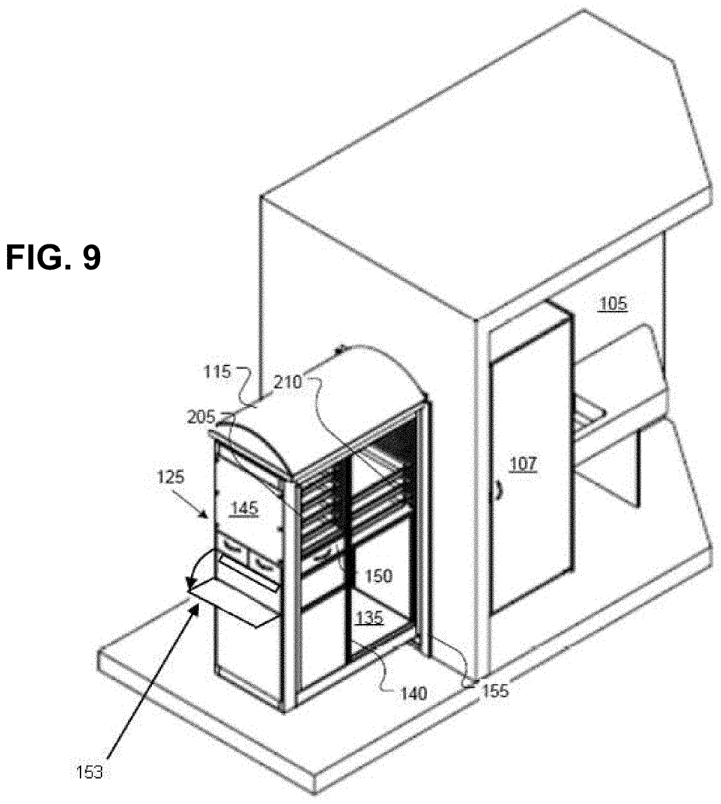

Referring to FIG. 9, another example of the cabinet 100 is similar to the cabinet 100 of FIGS. 1-7 and includes the same components identified by the same numbers. However, while the cabinet 100 of FIGS. 1-7, the cabinet 100 includes a pull-out drawer, the cabinet 100 of FIG. 9 includes a flip down cover 153 that can permit access to a keyboard tray 500 stored within the cabinet insert 125.

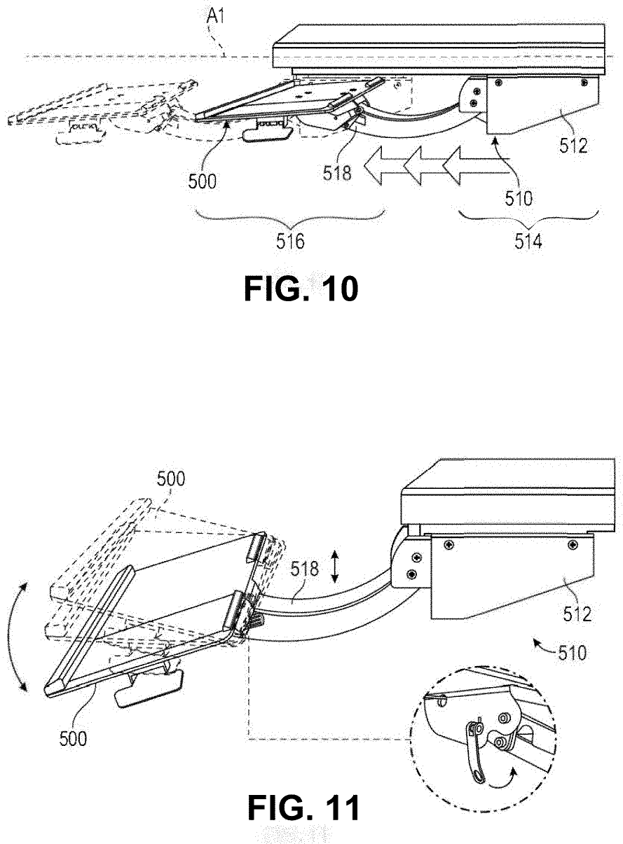

Referring to FIG. 10, the cabinet 100 further includes a mount assembly 510 attaching the keyboard tray 500 to the cabinet insert 125. The mount assembly 510 includes a shuttle bracket 512 connected to the cabinet insert 125. The shuttle bracket 512 is movable relative to the cabin insert 125 along a first axis A1 between a stowed position 514 and a deployed position 516. The mount assembly 510 further includes an arm 518 attached to the shuttle bracket 512, and the keyboard tray 500 pivotably attached to an end of the arm 518 (FIG. 11). The keyboard tray 500 is movable between the stowed position 514 where the keyboard is stored in the cabinet insert 125 and a deployed position 516 where a user may access the keyboard, in response to the shuttle bracket 512 being movable between the stowed position 514 and the deployed position 516.

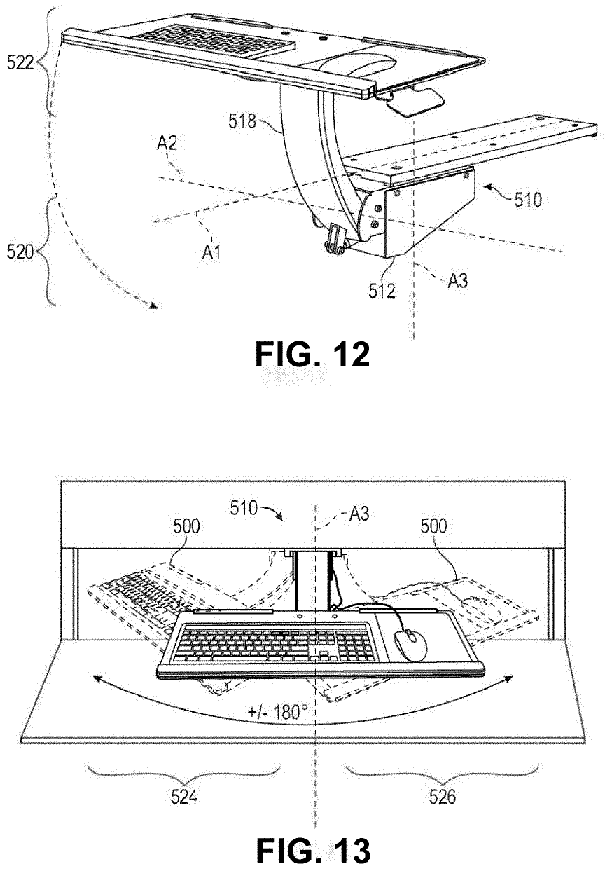

Referring to FIG. 12, the arm 518 is pivotably attached to an end of the arm 518 about a second axis A2 that is perpendicular to the first axis A1. The keyboard tray 500 and the arm 518 is movable between a lowered position 520 and a raised position 522 in response to the arm 518 pivoting about the second axis.

Referring FIG. 13, the keyboard tray of FIG. 10 is movable between first and second side positions. More specifically, the shuttle bracket 512 is pivotably attached to the cabin insert 125 for pivoting the mount assembly 510 about a third axis that is perpendicular to the first and second axes. The keyboard tray 500 is movable between a first side position 524 and a second side position 526.

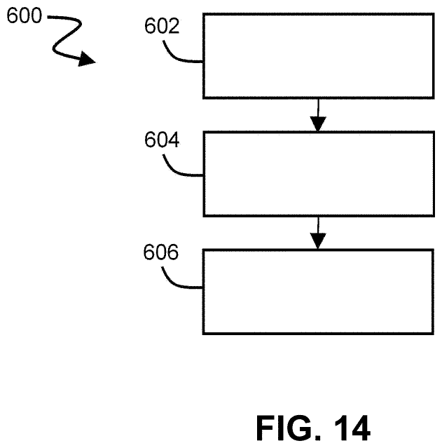

Referring to FIG. 14, one example of a method 600 is provided for operating the cabinet 100 of FIGS. 1-7. The method 600 begins at block 602 with translating the cabinet insert 125 between the retracted orientation (FIG. 1) and the extended orientation (FIG. 3). The method 600 then proceeds to block 604.

At block 604, the method 600 further includes allowing, using the lock 430, credentialed personnel access to the drawer 150 within the cabinet insert 125. Examples of the lock 430 include the key lock cylinder 431a, the digital keypad 431b, the radio frequency identification (RFID) lock 431c, and so forth. The lock 430 is actuated by an associated one of the RFID wristband 433a, the smart card 433b, the smart tag 433c, the smart key fob 433d, the smart identification badge 433e, and so forth for permitting access to the drawer within the cabinet insert. The method 600 then proceeds to block 606.

At block 606, the method 600 includes accessing a keyboard stored within the cabinet insert 125. More specifically, as shown in FIG. 10, the method 600 may include moving the keyboard tray 500 along the first axis A1 relative to the cabinet insert 125 between the stowed position 514 and the deployed position 516. As shown in FIG. 12, the method 600 may further include pivoting the keyboard tray 500 about a second axis A2 between the lowered position 520 and the raised position 522, with the second axis A2 being perpendicular to the first axis A1. As shown in FIG. 12, the method 600 may further include pivoting the keyboard tray 500 about a third axis A3 between the first side position 524 and the second side position 526, with the third axis A3 being perpendicular to the first and second axes A1, A2. In other examples, the keyboard tray or other carrier can be movable relative to the cabinet insert along other suitable degrees of freedom.

Although the subject matter has been described in language specific to structural features and/or process operations, it is to be understood that the subject matter defined in the appended claims is not necessarily limited to the specific features or acts described above. Rather, the specific features and acts described above are disclosed as example forms of implementing the claims.

The description of the present disclosure is merely exemplary in nature and variations that do not depart from the gist of the present disclosure are intended to be within the scope of the present disclosure. Such variations are not to be regarded as a departure from the spirit and scope of the present disclosure.

What is claimed is:

1. A server cabinet, comprising:
a cabinet frame that includes a housing structure, wherein the housing structure including an overhead structure; and
a cabinet insert translationally connected to the overhead structure such that the cabinet insert can transition between a retracted orientation and an extended orientation, wherein the cabinet insert includes a pull-out basket assembly configured to support a plurality of baskets.

2. The server cabinet as recited in claim 1, wherein the overhead structure includes a first base structure and a second base structure, wherein a portion of the overhead frame is disposed between the first base structure and the second base structure.

3. The server cabinet as recited in claim 2, wherein the first base structure, the second base structure, and the overhead frame comprise aluminum having a hollow profile.

4. The server cabinet as recited in claim 2, further comprising a rail system.

5. The server cabinet as recited in claim 4, wherein the rail system comprises a plurality of rails attached to the overhead frame and configured to retain rollers attached to the cabinet insert.

6. The server cabinet as recited in claim 1, further comprising a lock that is configured to allow credentialed personnel access to a drawer within the cabinet insert.

7. The server cabinet as recited in claim 6, wherein the lock comprises a radio frequency identification (RFID) lock.

8. The server cabinet as recited in claim 6, wherein the lock communicates with a wearable device including a RFID wristband for accessing the drawer within the cabinet insert.

9. The server cabinet as recited in claim 6, wherein the lock communicates with a smart card, a smart tag, a smart key fob, and a smart identification badge for accessing the drawer within the cabinet insert.

10. The server cabinet as recited in claim 6, wherein the lock comprises at least one of a key lock cylinder and a digital keypad.

11. A server cabinet, comprising:
a cabinet frame that includes a housing structure, wherein the housing structure including an overhead structure;
a cabinet insert translationally connected to the overhead structure such that the cabinet insert can transition between a retracted orientation and an extended orientation, wherein the cabinet insert includes a pull-out basket assembly configured to support a plurality of basket; and
a keyboard tray attached to the cabinet insert and movable between a stowed position and a deployed position.

12. The server cabinet as recited in claim 11, further comprising a mount assembly attaching the keyboard tray to the cabinet insert, with the mount assembly including a shuttle bracket that is movable relative to the cabin insert along a first axis between the stowed position and the deployed position.

13. The server cabinet as recited in claim 12, wherein the mount assembly further includes an arm attached to the shuttle bracket, with the keyboard tray pivotably attached to an end of the arm about a second axis that is perpendicular to the first axis, and the keyboard tray is movable between a lowered position and a raised position.

14. The server cabinet as recited in claim 13, wherein the shuttle bracket is pivotably attached to the cabin insert for pivoting the mount assembly about a third axis that is perpendicular to the first and second axes, and the keyboard tray is movable between a first and second side positions.

15. The server cabinet as recited in claim 14, wherein the cabinet insert defines an interior space with a mass scale stored in the interior space and the mass scale measuring a mass of items stored within the interior space.

16. The server cabinet as recited in claim 14, wherein the cabinet insert defines an interior space with a chute being accessible via an opening for delivering items to the interior space.

17. The server cabinet as recited in claim 14, wherein the overhead structure includes a first base structure and a second base structure, wherein a portion of the overhead frame is disposed between the first base structure and the second base structure, wherein the first base structure, the second base structure, and the overhead frame comprise aluminum having a hollow profile.

18. The server cabinet as recited in claim 17, further comprising:
a rail system having a plurality of rails attached to the overhead frame and configured to retain rollers attached to the cabinet insert; and
a lock that is configured to allow credentialed personnel access to a drawer within the cabinet insert; wherein the lock comprises a radio frequency identification (RFID) lock, a key lock cylinder, and a digital keypad;
wherein the lock is actuated by at least one of a smart card, a smart tag, a smart key fob, a smart identification badge, and a wearable device for permitting access to the drawer within the cabinet insert.

19. A method of operating a server cabinet having a cabinet frame and a cabinet insert, with the cabinet frame having a housing structure that includes an overhead structure, the cabinet insert being translationally connected to the overhead structure, the cabinet insert includes a pull-out basket assembly configured to support a plurality of baskets, and the server cabinet further including a keyboard tray attached to the cabinet insert, the method comprising:
translating the cabinet insert between a retracted orientation and an extended orientation; and
allowing, using a lock, credentialed personnel access to a drawer within the cabinet insert;
wherein the lock comprises a radio frequency identification (RFID) lock, a key lock cylinder, and a digital keypad; and
wherein the lock is actuated by at least one of a smart card, a smart tag, a smart key fob, a smart identification badge, and a wearable device for permitting access to the drawer within the cabinet insert.

20. The method as recited in claim 19, further comprising:
moving the keyboard tray along a first axis relative to the cabinet insert between a stowed position and a deployed position;
pivoting the keyboard tray about a second axis between a lowered position and a raised position, with the second axis being perpendicular to the first axis; and
pivoting the keyboard tray about a third axis between a first side position and a second side position, with the third axis being perpendicular to the first and second axes.
